(19) United States
(12) Patent Application Publication
(10) Pub. No.: US 2014/0326288 A1
(43) Pub. Date: Nov. 6, 2014

(54) SEMICONDUCTOR ELEMENT, THERMOELECTRIC MODULE, METHOD FOR PRODUCING A TUBULAR THERMOELECTRIC MODULE AND MOTOR VEHICLE

(71) Applicant: EMITEC GESELLSCHAFT FUER EMISSIONSTECHNOLOGIE MBH, Lohmar (DE)

(72) Inventors: SIGRID LIMBECK, MUCH (DE); ROLF BRUECK, BERGISCH GLADBACH (DE)

(21) Appl. No.: 14/334,700

(22) Filed: Jul. 18, 2014

Related U.S. Application Data
(63) Continuation of application No. PCT/EP2013/000129, filed on Jan. 17, 2013.

(30) Foreign Application Priority Data
Jan. 18, 2012 (DE) 102012000763.9

(51) Int. Cl. H01L 35/26; H01L 35/34

(52) U.S. Cl. CPC H01L 35/26; H01L 35/34
USPC 136/212; 136/200; 438/55; 136/201

(57) ABSTRACT

A semiconductor element for a thermoelectric module has opposite ends and is made of an n-doped or p-doped semiconductor material and at least one foreign material. The foreign material is mixed with the semiconductor material and forms a fraction of 25 to 75 vol % of the semiconductor element. A method for producing a tubular thermoelectric module includes providing an inner tube having an axis, an inner circumferential surface and a first outer circumferential surface, alternately placing n-doped and p-doped semiconductor elements in direction of the axis, placing second electrical conducting elements radially outwardly of the semiconductor elements so that pairs of adjacent semiconductor elements are electrically conductively connected to each other at the outside to then form a second outer circumferential surface, and compressing the thermoelectric module. A motor vehicle having a thermoelectric module is also provided.

### CROSS-REFERENCE TO RELATED APPLICATION

This is a continuation, under 35 U.S.C. §120, of copending International Application No. PCT/EP2013/000129, filed Jan. 17, 2013, which designated the United States; this application also claims the priority, under 35 U.S.C. §119, of German Patent Application DE 10 2012 000 763.9, filed Jan. 18, 2012; the prior applications are herewith incorporated by reference in their entirety.

### BACKGROUND OF THE INVENTION

### Field of the Invention

The present invention relates to a semiconductor element for use in a thermoelectric module. The invention also relates to a thermoelectric module, a method for producing a tubular thermoelectric module and a motor vehicle.

A thermoelectric module is suitable for generating electrical energy, for example from the exhaust gas of an internal combustion engine, by using a generator. That refers, in particular, to a generator for converting thermal energy of an exhaust gas into electrical energy, that is to say a so-called thermoelectric generator.

The exhaust gas from an internal combustion engine of a motor vehicle has thermal energy which can be converted by using a thermoelectric generator into electrical energy, for example in order to charge a battery or some other energy storage device and/or to supply required energy directly to electrical consumers. In that way, the motor vehicle is operated with improved energy efficiency, and more energy is available for the operation of the motor vehicle.

A thermoelectric module has at least a multiplicity of thermoelectric elements. Thermoelectric materials are materials which can convert thermal energy into electrical energy (Seebeck effect) and vice versa (Peltier effect) in an effective manner. Thermoelectric elements include, for example, at least two semiconductor elements (p-doped and n-doped) which, at their mutually opposite ends that are respectively oriented toward a hot side and toward a cold side, are provided with electrically conductive bridges in an alternating manner. In a thermoelectric module, numerous such semiconductor elements are connected electrically in series. In order to ensure that the potential differences generated by the semiconductor elements in series do not cancel one another out, it is always the case that semiconductor elements with different majority charge carriers (n-doped and p-doped) are placed in direct electrical contact in an alternating manner. The electrical circuit can be closed, and electrical power thus tapped off, by using a connected load resistor.

It has already been attempted to provide corresponding thermoelectric modules for use in motor vehicles, in particular in passenger motor vehicles. They were, however, generally very expensive to produce and distinguished by relatively low efficiency. It has thus heretofore not been possible to achieve suitability for mass production.

### SUMMARY OF THE INVENTION

It is accordingly an object of the invention to provide a semiconductor element, a thermoelectric module, a method for producing a tubular thermoelectric module and a motor vehicle, which overcome the hereinafore-mentioned disadvantages and at least partially solve the highlighted problems of the heretofore-known semiconductor elements, modules, methods and vehicles of this general type. In particular, it is sought to specify a semiconductor element which permits improved efficiency with regard to the conversion of provided thermal energy into electrical energy when used in a thermoelectric module. In this case, consideration should also be given to the amount of expensive semiconductor material that has to be used. Furthermore, it is sought to specify a method for producing a thermoelectric module in which the method can be implemented in the simplest possible manner and produces a thermoelectric module which can be used reliably under fluctuating temperature potentials, in particular when used in a motor vehicle.

These objects are achieved by a semiconductor element, a thermoelectric module, a method for producing a thermoelectric module and a vehicle according to the invention. Advantageous embodiments of the semiconductor element according to the invention and the integration of the semiconductor element into superordinate structural units (thermoelectric module, thermoelectric generator) and the use thereof are specified in the dependent claims. The features specified individually in the claims may be combined with one another in any desired technologically expedient manner and form further embodiments of the invention. This means, in particular, that the explanations directed to the semiconductor element can likewise be applied to the stated thermoelectric module and also to the method for producing a tubular thermoelectric module. The description, in particular in conjunction with the figures, explains the invention further and specifies supplementary exemplary embodiments of the invention.

With the foregoing and other objects in view there is provided, in accordance with the invention, a semiconductor element for use in a thermoelectric module. The semiconductor element has mutually opposite ends and is formed from an n-doped or p-doped semiconductor material and at least one foreign material. The foreign material is mixed with the semiconductor material. The foreign material makes up a fraction of 5 vol % to 75 vol % [percent by volume] of the semiconductor element. In particular, the foreign material makes up a fraction of 25 vol % to 75 vol %, preferably a fraction of 50 vol % to 75 vol % and particularly preferably a fraction of 60 vol % to 75 vol % of the semiconductor element.

In particular, one of the following materials is used as the semiconductor material:

| Type: | Material: |
|---|---|
| V-VI | Bi₂Te₃ |
| IV-VI | PbTe |
| Zn₄Sb₃ | Zn₄Sb₃ |
| Silicides | p-MnSi_{1.73} |
| | n-Mg₂Si_{0.4}Sn_{0.6} |
| | Si_{0.80}Ge_{0.20} |
| | Si_{0.94}Ge_{0.06} |
| Skutterudite | CoSb3 |
| Semi-Heusler | TiNiSn |
| n/p-clathrates | Ba₈Ga₁₆Ge₃₀ |
| Oxides | p-NaCo₂O₄ |
| Zintl phases | p-Yb₁₄MnSb₁₁ |
| Th₃P₄ | La_{3-X}Te₄ |

The foreign material is, in particular, integrated and/or embedded into the semiconductor element. The foreign material preferably forms a fixedly connected and/or captive constituent part of the semiconductor element. The filler material is mixed with the semiconductor material, in particular, in a uniform fashion, in such a way that a homogeneous distribution of the foreign material in the semiconductor material is realized. It must, however, be taken into consideration in this case that the foreign material is not present in the same grain size as the semiconductor material, and may be present in some other external form/shape (for example fibers). Correspondingly, the expression “homogeneous” refers to the fact that at least the overwhelming majority, or all, of the sub-volumes of the semiconductor element (for example up to a 1:10 split of the semiconductor element) have a substantially uniform distribution of the fractions of foreign material and semiconductor material.

In accordance with another advantageous feature of the semiconductor element of the invention, the at least one foreign material has, in a temperature range from 20° C. to 600° C., at least one characteristic from the following group:
greater tensile strength Rₘ and/or yield strength R_{p0.2} than the semiconductor material,
lower specific thermal conductivity [watt/(kelvin*meters)] than the semiconductor material,
lower electrical conductivity [amperes/(volts*meters)] than the semiconductor material.
   It is furthermore preferable for multiple or all of the characteristics to be present.

The characteristic assists in the realization of the desired functions of the semiconductor element, such as for example the improvement of the tensile strength, a (possibly locally predefined or adapted) thermal conductivity and/or an adapted electrical conductivity, wherein the latter characteristics can be used, in particular, to improve the efficiency of the thermoelectric material.

It is provided, in particular, that the foreign material is in this case disposed as a thermal insulation material within the semiconductor element.

It is provided, in particular, that the foreign material is not used as an electrical conductor, that is to say in this case does not perform a function of the thermoelectric material (Seebeck/Peltier effect). In particular, the thermoelectric effect is realized exclusively by using the semiconductor material in the semiconductor element.

In particular, the use of the foreign material within the semiconductor element makes it possible for the thermal conductivity of a thermoelectric module constructed with corresponding semiconductor elements to be set, at one operating point, in such a way that between 30% and 70%, in particular between 40% and 60%, of the overall temperature difference (between an exhaust gas and a coolant) prevails across the thermoelectric module, that is to say between a hot side and a cold side.

In each case the semiconductor elements have one end face surface at their ends facing toward the hot side and toward the cold side, through which they are in heat-conducting contact with the respective hot side and cold side. In this case, it is not of importance for the respective ends to be provided, for example, with electrical conductor elements or for the electrical conductor elements to have additional electrical insulation with respect to the respective hot side or cold side. In this case, the areal coverage of the cold side and/or hot side by the respective end face surface of the semiconductor elements is of importance because the areal loading simultaneously describes the space utilization or area utilization of the hot side and/or cold side and/or of the intermediate space present between the hot side and cold side. In other words, this also means that, at the respective ends of the semiconductor elements, at most 95%, in particular at most 75%, preferably at most 60%, particularly preferably at most 50% and very particularly preferably at most 25% of a respective cross-sectional area present within the semiconductor element is formed by the semiconductor material.

The hot side and the cold side delimit the intermediate space that is available for the configuration of the semiconductor elements within the thermoelectric module. The hot side and the cold side are, in particular, connected by closure elements, in such a way that the intermediate space is, in particular, enclosed and formed by the hot side, the cold side and closure elements. It has heretofore been assumed that the greatest possible space utilization of the intermediate space or the greatest possible area utilization on the hot side and/or the cold side for thermoelectric material is necessary in order to permit a high level of conversion of the available thermal energy into electrical energy by using a thermoelectric module or thermoelectric generator.

The space utilization and the selection of the foreign material provided in this case are preferably geared (exclusively) to the requirements for the mechanical and chemical stability of the thermoelectric module. In this case, use is made of the finding that the space utilization for thermoelectric semiconductor material and the selection of the foreign material should be coordinated with one another in order to adapt the thermal resistances of the individual functional layers (hot side, cold side, semiconductor elements) to one another. By using this specific adaptation of the configuration and fractions of semiconductor material and foreign material, the overall temperature difference between the exhaust gas of the hot side and a coolant at the cold side can be utilized by the thermoelectric module in such a way as to give rise to an increase in power.

In simple terms, the electrical power that can be generated by the thermoelectric module is determined by the product of the thermoelectric efficiency of the module and the heat flow Q entering on the relatively hot side of the thermoelectric module. In general, the thermoelectric efficiency increases with increasing thermal resistance of the functional layer between the hot side and the cold side, because this results in an increase in the temperature difference between the hot side and the cold side. By contrast, the heat flow decreases due to the increased thermal resistance. This means, in particular, that the electrical power is a function of the thermal resistance of the thermoelectric module. The thermal resistance of the thermoelectric module is determined from the thermal conductivity of the semiconductor element (that is to say, in this case, semiconductor material and foreign material), the geometric dimensions of the semiconductor elements, the thermal conductivity of the electrical insulation disposed between the semiconductor elements, and the geometric dimensions thereof. Accordingly, disregarding thermal contact resistances for the thermal resistance of the module (R_{module}), the following equation applies:

R_{module}=x/(λ_{TE}*A_{TE}+λᵢₙₛᵤₗₐₜᵢₒₙ*λᵢₙₛᵤₗₐₜᵢₒₙ),

where:
x: is the height of the thermoelectric module, that is to say the spacing between the hot side and the cold side of the thermoelectric module,
λ_{TE}: is the thermal conductivity of the semiconductor elements,
λᵢₙₛᵤₗₐₜᵢₒₙ: is the thermal conductivity of the electrical insulation
A_{TE}: is the area of the semiconductor elements perpendicular to the heat flow (in particular, the cross section through the semiconductor elements),
Aᵢₙₛᵤₗₐₜᵢₒₙ: is the area of the electrical insulation perpendicular to the heat flow (in particular, the cross section through the electrical insulation).

The convective resistance (R_{convective}) is defined as:

R_{convective}=1/(α*A)

where α denotes the heat transfer coefficient and A denotes the corresponding surface under consideration. The smallest area unit A_{EZ} considered in this case for the comparison of R_{convective} and R_{module} corresponds to the cross-sectional area of a so-called unitary cell. The unitary cell includes that region of a thermoelectric module which includes in each case one n-doped and p-doped semiconductor element and the electrical insulation disposed in between. The following thus applies:

A_{TE}+Aᵢₙₛᵤₗₐₜᵢₒₙ=A_{EZ}

The overall temperature difference prevailing between, for example, an exhaust gas flowing past on the hot side and a coolant flowing past on the cold side is split in the ratio of the individual thermal resistances R_{convective} (in each case for the hot side and for the cold side) and R_{module}. The temperature difference that thus prevails between the hot side and the cold side of the thermoelectric module is correspondingly proportional to the thermal resistance of the thermoelectric module R_{module}. The heat flow Q that can be converted into electrical current by the semiconductor elements is accordingly determined from the ratios of the resistances R_{convective} and R_{module} to one another, and is inversely proportional to R_{module}. Further heat flows in the thermoelectric element are the Peltier heat flow and the ohmic heat flow caused by the ohmic resistance of the semiconductor materials of the thermoelectric elements.

The heat flow Q flowing through the thermoelectric module can be correspondingly calculated from the quotient ΔT/R_{module}, where ΔT denotes the temperature difference between the hot side (T_{h, TM}) and the cold side (T_{k, TM}) and R_{module} denotes the thermal resistance of the thermoelectric module. The electrical power that can be generated by the thermoelectric module can thus be influenced significantly by the thermal resistance of the thermoelectric module. A heat flow passes from the hot side to the cold side through the semiconductor elements in a manner dependent on the characteristics of the semiconductor material and of the foreign material. The higher the specific thermal conductivity of the semiconductor element is, the lower the temperature difference, available for the generation of electricity is, between the hot-side end and the cold-side end of the semiconductor element. The invention has now realized a significant adaptation between firstly the semiconductor material, which is important for the generation of electricity and which connects the hot side to the cold side firstly for electrical generation from the temperature difference but secondly also in heat-conducting fashion, and secondly improved heat insulation between the hot side and the cold side (for example by using the foreign material), in such a way that a high temperature difference prevails at the respective ends of the semiconductor elements at the hot side and at the cold side, and at the same time, a large heat flow passes through the semiconductor elements from the hot side to the cold side of the thermoelectric module.

It is now proposed in this case, in particular, that the intermediate space between hot side and cold side no longer be filled as completely as possible with semiconductor material, but that, on the contrary, a large part of the area available for semiconductor elements on the hot side and on the cold side, or of the intermediate space present between hot side and cold side, be filled, in particular, with thermally insulating and thermoelectrically inactive foreign material. In particular, the remaining (small) volume of the intermediate space between the semiconductor elements is filled with electrical insulation.

The thermal conductivity of the thermoelectric module at a (predefined) operating point of the thermoelectric module is set, by way of the predetermined fraction of foreign material, in such a way that between 40% and 60% of the overall temperature difference between, for example, an exhaust gas flowing past on the hot side and a coolant flowing past on the cold side prevails across the thermoelectric module (that is to say between hot side and cold side). In other words, this also means that, for a predetermined operating point of the thermoelectric module, the sum of the convective resistances R_{convective} of the hot side and of the cold side of the thermoelectric module amounts to between 80 (Y0 and 120% of the value of the thermal resistance of the thermoelectric module R_{module}.

With increasing thermal resistance of the thermoelectric module, the temperature difference, that can be utilized for the generation of electricity, between the hot side and the cold side of the thermoelectric module increases. The thermoelectric efficiency profits from an increasing temperature difference in an approximately linear manner. In exchange for this, however, the heat flow passing through the thermoelectric module decreases because, with increasing thermal resistance of the thermoelectric module, the overall resistance (sum of R_{convective} and R_{module}) also increases. There is thus a maximum power of the overall configuration which is dependent on the thermal resistance. It can be assumed, by way of approximation, that the electrical power is at a maximum when half of the overall temperature difference (exhaust gas/coolant) prevails across the thermoelectric module. That is to say, the following should approximately apply:

R_{convective-hot side}+R_{convective-cold side}=R_{module}

The thermal resistance of the thermoelectric module can be set inter alia by way of the fraction of foreign material in the semiconductor elements. The thermal resistance of the thermoelectric module may also be set by way of non-constant cross sections of the semiconductor elements and/or by way of porous semiconductor elements. The fraction of semiconductor material in the intermediate space of the thermoelectric module will hereinafter be referred to as the fill ratio. If the entire intermediate space available between the hot side and the cold side for the installation of semiconductor elements is filled with semiconductor material, the fill ratio is 1, or 100%. If only half of the intermediate space is filled with semiconductor material, the fill ratio is 0.5, or 50%. If air, for example, is used as an electrical insulation between semiconductor elements which, in the following example, are composed of 100% semiconductor material, the thermal resistance of the thermoelectric module is approximately twice as high in the case of a configuration with a fill ratio of 0.5 as in the case of a fill ratio of 1. The reason for this is the smaller available area through which the heat flow can pass. By way of the fill ratio, the thermal resistance of the thermoelectric module can be set in such a way that a maximum amount of electrical power can be generated. That is to say, much less (expensive) thermoelectric material is required, and at the same time, the electrical power is increased through the setting of the thermal resistance of the thermoelectric module.

Simulations have confirmed these findings. An exemplary result is shown in the following table:

TABLE 1
Simulation results for a fill ratio variation

| Fill | Insulation | | | | | | | |
|---|---|---|---|---|---|---|---|---|
| ratio | material | λ_{eff} | T_{h, TM} | T_{k, TM} | Q_{parasitic} | Q_{TM} | Efficiency | Pₑₗ |
| [—] | [—] | [W/mK] | [° C.] | [° C.] | [W] | [W] | [—] | [W] |
| 0.9 | Air | 1.2 | 164 | 95 | 0.006 | 1.92 | 1.52 | 0.029 |
| 0.66 | Air | 0.9 | 183 | 95 | 0.025 | 1.81 | 1.83 | 0.034 |
| 0.3 | Air | 0.5 | 240 | 95 | 0.092 | 1.42 | 2.51 | 0.038 |

It can be seen that, with decreasing fill ratio, the effective thermal conductivity (λ_{eff}) decreases. In this case, the effective thermal conductivity describes a substitute value for a unitary cell which is composed of a parallel path of the semiconductor element (in this case composed 100% of semiconductor material) and of the electrical insulation. That is to say, the following applies:

(A_{TE}*A_{TE}+Aᵢₙₛᵤₗₐₜᵢₒₙ*Aᵢₙₛᵤₗₐₜᵢₒₙ)/(A_{TE}+Aᵢₙₛᵤₗₐₜᵢₒₙ)=A_{eff}

Due to the decreasing effective thermal conductivity, the temperature difference across the module increases (Tₕ, T_{V} 164 to 240° C., by contrast to T_{k, TM}: 95° C.), which in turn has a positive influence on efficiency (efficiency: 1.52 to 2.51). This results, overall, in an increase in electrical power (Pₑₗ) by 30%, with a simultaneous reduction in the use of semiconductor material by 66%. The results shown are based on a predetermined operating point and a predetermined convective heat transfer. The thermoelectric module can likewise be adapted to specific requirements (for example differences between Diesel or Otto-cycle internal combustion engines in terms of exhaust-gas enthalpy) during operation.

Q_{parasitic} is that fraction of the heat flow entering on the hot side of the thermoelectric module which flows not through the semiconductor material but, in this example, through the electrical insulation (in this case air) disposed in parallel. With regard to the present invention, Q_{parasitic} encompasses that fraction of the heat flow which flows through the foreign material and through the electrical insulation.

Aside from the increase in power, variation of the fill ratio parameter can also be used to set the temperature on the hot side of the thermoelectric module (T_{h, TM}), in such a way that overheating during the operation of a thermoelectric module in an exhaust system can be prevented.

In this case, “operating point” refers to a state for which the thermoelectric module is to be constructed and which generally prevails at the installation site of the thermoelectric module. The operating point includes, for example, exhaust gas temperatures, coolant temperatures, exhaust-gas mass flow rate, coolant mass flow rate, etc.

Through the use of foreign material in the semiconductor element, thermal insulation is realized which is coordinated with the heat flow, in such a way that power-reducing parasitic heat flows within the thermoelectric module, parallel to the thermoelectric material, are minimized. Through the use of the semiconductor element according to the invention, the useful electrical power can be maximized by using a correspondingly constructed thermoelectric module, and at the same time, the use of expensive semiconductor material can be reduced. Advantages are also obtained with regard to the construction of the thermoelectric module, because it is now possible to dispense with the use of filler material between the semiconductor elements.

In accordance with a further advantageous feature of the semiconductor element of the invention, the foreign material is present in the form of fibers and/or grains. More elongate structures of the foreign material are referred to in this context as fibers. In this case, the ratio of greatest thickness to greatest length is at least 2, in particular at least 30 or even at least 100. Correspondingly, the structure of the foreign material is referred to as a grain if the ratio of greatest thickness to greatest length is less than 2.

In accordance with an added preferable feature of the semiconductor element of the invention, the fraction of grains in the foreign material is at least 30 vol %. This means that at most 70 vol % of the foreign material is present in the form of fibers. In particular, the fraction of grains in the foreign material is at least 50% and is preferably 80%. It is particularly preferable for the foreign material to be provided exclusively in the form of grains.

In accordance with an additional advantageous feature of the semiconductor element of the invention, grains and fibers are distributed differently in the semiconductor element, wherein grains are present in a greater fraction than the fibers at the ends of the semiconductor element and the fibers are present in a greater fraction than the grains in a central region between the ends of the semiconductor element. The central region encompasses, in particular, a region which is disposed centrally between the ends of the semiconductor element and which covers approximately 50% of the height of the semiconductor element.

In accordance with yet another preferable feature of the semiconductor element of the invention, the at least one foreign material is present at least partially in the form of fibers and the fibers are disposed substantially in at least one first direction parallel to the ends and/or in a second direction that runs transversely with respect to the first direction.

By using the orientation of the fibers within the semiconductor element, it is possible to obtain directional characteristics of the semiconductor element. In this case, a directional characteristic means that the semiconductor element has different characteristics, for example, in a first direction than in a second direction. For example, through corresponding selection and configuration of the fibers, it is possible to set directional values for strength, ductility or thermal expansion of the semiconductor element.

In accordance with yet a further feature of the semiconductor element of the invention, every cross section of the semiconductor element running parallel to the ends has a fraction of foreign material which lies in a range between 25% and 75%, wherein it is preferably provided that the fraction of foreign material lies in a range between 50% and 75%, and particularly preferably between 60% and 75%.

The use of the foreign material in the semiconductor element thus, in particular, also replaces the material (electrical insulation) with no thermoelectric characteristics that has heretofore been used as (external and/or separate) filler material between semiconductor elements. In this way, it is possible for the preferred configuration of a thermoelectric module with regard to thermal resistance to be realized simply on the basis of the construction of the semiconductor elements. The temperature difference, that can be utilized for the generation of electricity, between the hot side and the cold side of the thermoelectric module is thus determined substantially exclusively on the basis of the configuration of the semiconductor elements. By using the foreign material used in the semiconductor element, the heat flow passing through the thermoelectric module between the hot side and the cold side is correspondingly reduced, because with increasing thermal resistance of the thermoelectric module, the overall resistance is also increased. It is correspondingly possible for the foreign material, which in particular has no thermoelectric characteristics, to be used (exclusively) for the mechanical and, if appropriate, chemical stabilization of the semiconductor element. The use of the foreign material does not result in a reduction in the thermoelectric efficiency of the semiconductor element. Surprisingly, an improvement in the thermoelectric efficiency of a thermoelectric module is achieved with the use of the semiconductor elements. Furthermore, due to the combination of the functional characteristics of semiconductor material and foreign material, the construction, and the method for producing a thermoelectric module, are simplified significantly.

With the objects of the invention in view, there is also provided a thermoelectric module, comprising a hot side, a cold side and an intermediate space disposed therebetween, the intermediate space accommodating, at least partially or exclusively, semiconductor elements according to the invention. The semiconductor elements are connected to one another in an electrically conductive manner, wherein at least 80 vol %, in particular at least 90 vol % and preferably at least 95 vol %, particularly preferably at least 99 vol %, of the intermediate space of the thermoelectric module is filled with semiconductor elements.

In accordance with another advantageous feature of the thermoelectric module of the invention, those semiconductor elements which are disposed in each case adjacent one another are separated from one another by an electrical insulation material with a thickness of less than 0.5 mm [millimeters], in particular of less than 0.1 mm and preferably of less than 0.01 mm.

The electrical insulation material may, in particular, be connected to the semiconductor elements. For example, the electrical insulation material may be applied in the form of a coating to the semiconductor element. The electrical insulation material may also be disposed as a separate component between mutually adjacently disposed semiconductor elements.

In accordance with a further feature of the thermoelectric module of the invention, the electrical insulation material for the thermoelectric module is a mica material.

Mica is a phyllosilicate in which the unitary structure is formed of an octahedral sheet (Os) between two opposite tetrahedral sheets (Ts). The sheets form a layer which is separated from adjacent layers by areas of unhydrated interlayer cations (I). The sequence is: . . . . I Ts Os Ts I Ts Os Ts . . . . The composition of the Ts is T₂O₅. The coordinating anions around the octahedrally coordinated cations (M) are formed of oxygen atoms of the adjacent Ts and anions A. The coordination of the interlayer cations is nominally 12-fold, with a simplified formula that can be written as follows:

IM₂₋₃X₁₋₀T₄O₁₀A₂

where:

### I=Cs, K, Na, NH4, Rb, Ba, or Ca

### M=Li, Fe⁺⁺ or Fe⁺⁺⁺, Mg, Mn⁺⁺ or Mn⁺⁺⁺, Zn, Al, Cr, V, or Ti

### T=Be, Al, B, Fe⁺⁺⁺, or Si

A=CI, F, OH, O (oxy-mica), or S.

The following materials are very particularly preferred in this context: micanites (that is to say, in particular, mica fragments compacted and baked with synthetic resin to form large mica films) with high resistance to heat conduction.

In accordance with an added preferred feature of the thermoelectric module of the invention, in one embodiment at least 99 vol % of the intermediate space is formed by material in a solid state of aggregation. It is preferable for 99.9 vol % of the intermediate space to be formed by material in a solid state of aggregation. In particular, there are no gaseous or liquid inclusions present in the thermoelectric module.

With the objects of the invention in view, there is furthermore provided a method for producing a tubular thermoelectric module, the method comprising at least the following steps:

a) Providing an inner tube with an axis, an inner circumferential surface, a first outer circumferential surface, and first electrical conductor elements disposed on the first outer circumferential surface and constructed to be electrically insulated with respect to the inner circumferential surface;
b) Placing n-doped and p-doped semiconductor elements in an alternating manner in the direction of the axis, wherein in each case one electrical insulation is disposed between the semiconductor elements;
c) Placing second electrical conductor elements on the radially outer side of the semiconductor elements in such a way that in each case two mutually adjacently disposed semiconductor elements are connected to one another in an electrically conductive manner at the outside and, in particular, mutually adjacently disposed second electrical conductor elements are separated from one another by an electrical insulation or by an external electrical insulation, to form a second outer circumferential surface after step c); and
d) Compacting the thermoelectric module.

It is possible, in particular, for the cross sections of the tubular thermoelectric module to be of circular, elliptical or polygonal construction. In particular, the n-doped and/or p-doped semiconductor elements have a closed form in a circumferential direction, so that they can be pushed onto the first outer circumferential surface of the inner tube.

In the case of a tubular construction of the thermoelectric module, it is preferable for at least some of the semiconductor elements to also have a circular-ring-shaped form and to in each case be in contact, by way of an outer circumferential surface and an inner circumferential surface, with the hot side and with the cold side, respectively. The outer and inner circumferential surfaces then respectively form that face surface of the semiconductor element which is in contact with the hot side and cold side, respectively, of the thermoelectric module. The expression “circular-ring-shaped” thus means that the semiconductor element resembles at least a section of a circular ring. Semiconductor elements of such shape are proposed, in particular, for tubular thermoelectric modules. In this case, the hot side and the cold side respectively form the outer and the inner circumferential surface of a tube, in such a way that, in particular, a double tube wall is formed, in the intermediate space of which the semiconductor elements are disposed. In the case of a thermoelectric module of such construction, a coolant flows through a duct formed by the inner circumferential surface of the inner tube, and an exhaust gas (or some other hot fluid) flows over the second, outer circumferential surface (or vice versa), in such a way that a temperature difference can be generated across the double tube wall.

The semiconductor elements may, in particular, also have the shape of a circular ring segment. The semiconductor elements are then disposed adjacent one another or one behind the other along an axial direction of the thermoelectric module. The circular ring shape may in this case, in particular, correspond to a circular shape, although oval embodiments are also possible. With regard to the interconnection of the semiconductor elements, it is for example also possible for the semiconductor elements to have a 180° circular ring shape, with the semiconductor elements then being electrically connected to one another in an offset, alternating manner.

In particular, the electrical insulation is already disposed, for example in the form of a coating, on the n-doped and/or p-doped semiconductor elements before step b). In particular, the electrical insulation is likewise provided in the form of an individual structural element that is of closed form in the circumferential direction, which structural element is correspondingly pushed onto the first outer circumferential surface of the inner tube.

In particular, the configuration of second electrical conductor elements is realized by virtue of pushing on correspondingly constructed rings, which have a closed form in the circumferential direction. In particular, it is also possible for the second electrical conductor elements to be applied to the semiconductor elements by way of a printing or spraying process. The same applies to an external electrical insulation which may be required and which electrically insulates the second electrical conductor elements from one another. The second, external electrical insulation may however also be realized by virtue of adjacent second electrical conductor elements being spaced apart from one another.

It is provided, in particular, that the electrical insulation introduced in step b) is also provided as electrical insulation for the second electrical conductor elements. Correspondingly, steps b) and c) of the method are, in particular, performed alternately.

In particular, the first electrical conductor elements which are disposed on the first outer circumferential surface and which are intended to electrically connect in each case mutually adjacently disposed semiconductor elements to one another are electrically insulated from one another in the direction of the axis. In particular, the insulation is already disposed on the first outer circumferential surface between the first electrical conductor elements in step a).

In particular, the compaction of the thermoelectric module is performed by virtue of a pressure being imparted from the inside and/or from the outside through the inner tube or through the second outer circumferential surface. In particular, the compaction additionally takes place under the influence of temperature, that is to say, in particular, at temperatures of over 150° C.

In one particularly advantageous embodiment, sintering of the individual components of the thermoelectric module takes place during the compaction, in such a way that any existing porosity is reduced or eliminated entirely. In particular, step d) has the effect that (cohesive) connections are produced between the individual components of the thermoelectric module (in particular between electrical conductor elements and semiconductor elements and/or between electrical insulation and semiconductor elements). Cohesive connections refer to all connections in which the connecting partners are held together by atomic or molecular forces. They are, at the same time, non-releasable connections which can be severed only by destruction of the connecting measures (brazing, welding, adhesive bonding, etc.).

In accordance with another advantageous mode of the method of the invention, an outer tube is disposed on the second outer circumferential surface of the tubular thermoelectric module after step c), and the compaction according to step d) is performed only thereafter.

In particular, in the case of the method and the thermoelectric module produced by using the method, a dimensionally rigid outer tube is dispensed with. Correspondingly, the second outer circumferential surface may be formed by the second electrical conductor elements or by an additionally applied electrical insulation layer. The electrical insulation layer may be formed, in particular, through the use of a deformable sleeve. The deformable sleeve is, for example, a shrink hose, which firstly exhibits good thermal conductivity and secondly exhibits a degree of elasticity such that thermal expansions of the thermoelectric module can be absorbed by the deformable sleeve. The deformable sleeve thus replaces a dimensionally rigid outer tube (and at the same time an electrical insulation material disposed on the outer tube).

With the objects of the invention in view, there is concomitantly provided a motor vehicle comprising at least a heat source and a cooling configuration, wherein:
a thermoelectric module with semiconductor elements according to the invention, or
a thermoelectric module produced by using the method according to the invention,
   is disposed between the heat source and the cooling configuration.

In this case, the exhaust gas of an internal combustion engine, or a correspondingly interposed medium (fluid, gas) which is used for the transmission of thermal energy from an exhaust gas to the thermoelectric module is used, for example, as the heat source. The cooling configuration or cooler is, for example, connected to the cooling configuration of the internal combustion engine, and is traversed by a flow of water or some other coolant.

It is expressly pointed out in this case that the method according to the invention may also be used independently of the semiconductor elements according to the invention. It is, however, particularly preferable for proposed methods to be carried out using the semiconductor elements according to the invention. Correspondingly, the thermoelectric module that is formed at least partially with semiconductor elements according to the invention can be produced, in particular, by using the method according to the invention.

Other features which are considered as characteristic for the invention are set forth in the appended claims.

Although the invention is illustrated and described herein as embodied in a semiconductor element, a thermoelectric module, a method for producing a tubular thermoelectric module and a motor vehicle, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a block diagram of a structural variant of a motor vehicle with a diagrammatic, longitudinal-sectional view of a thermoelectric generator;

FIG. 2 is an enlarged, longitudinal-sectional view of a structural variant of a thermoelectric module;

FIG. 3 is a perspective view of a structural variant of a semiconductor element;

FIG. 4 is a perspective view of a further structural variant of a semiconductor element;

FIG. 5 is a fragmentary, perspective view of a fiber;

FIG. 6 is a longitudinal-sectional view of a further structural variant of a thermoelectric module;

FIG. 7 is a perspective view of a structural variant of an annular semiconductor element;

FIG. 8 is a longitudinal-sectional view of a portion of the further structural variant of a thermoelectric module;

FIG. 9 is a diagram showing a qualitative profile of efficiency, of heat flow and of electrical power as a function of thermal resistance of the thermoelectric module;

FIG. 10 is a longitudinal-sectional view showing method step a) of the method according to the invention;

FIG. 11 is a longitudinal-sectional view showing method step b) of the method according to the invention;

FIG. 12 is a longitudinal-sectional view showing method step c) of the method according to the invention;

FIG. 13 is a longitudinal-sectional view showing a method variant of the method according to the invention; and

FIG. 14 is a longitudinal-sectional view showing method step d) of the method according to the invention.

### DETAILED DESCRIPTION OF THE INVENTION

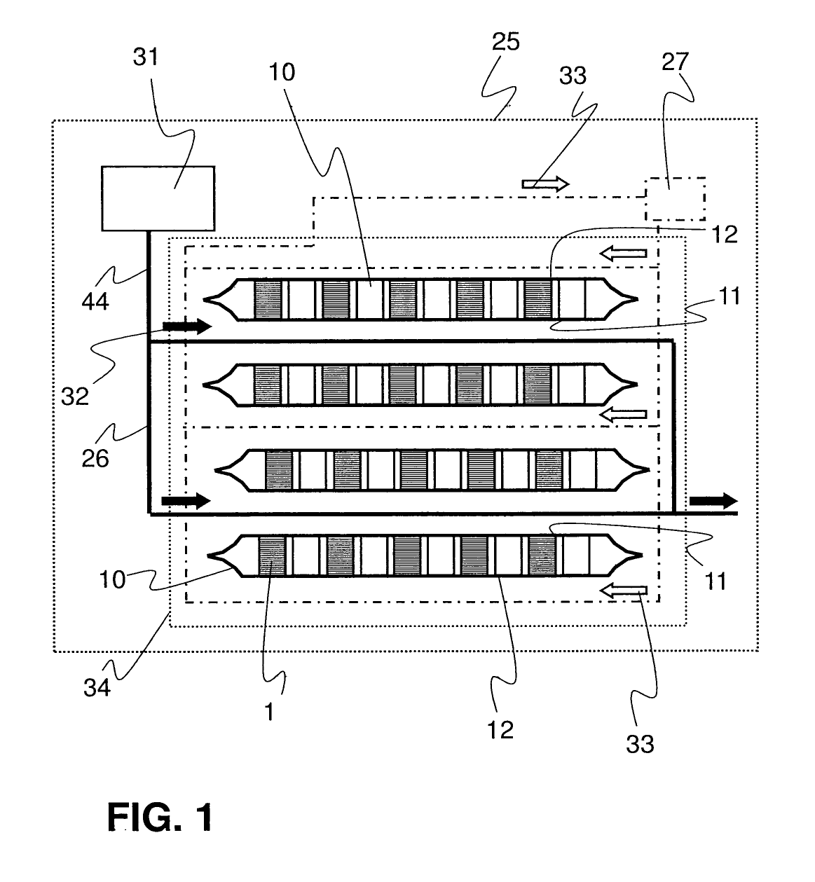

Referring now in detail to the figures of the drawing, in which the same reference numerals are used for identical objects to explain the invention and the technical field in more detail by showing particularly preferred structural variants to which the invention is not restricted, and first, particularly, to FIG. 1 thereof, there is seen an embodiment of a motor vehicle 25 with a thermoelectric generator 34. The motor vehicle 25 has an internal combustion engine 31 with an exhaust system 44. Exhaust gas 32 flows through the exhaust system 44. The exhaust system 44 serves in this case as a heat source 26 for the thermoelectric generator 34. The thermoelectric generator 34 is formed by multiple thermoelectric modules 10 which are disposed parallel to one another. The exhaust gas 32 is conducted through, between the thermoelectric modules 10, in such a way that a hot side 11 is formed on the thermoelectric module 10. The motor vehicle 25 furthermore has a cooling configuration or cooler 27 which conducts a coolant 33 to the thermoelectric module 10, in such a way that a cold side 12 is also formed on the thermoelectric module 10. The thermoelectric modules 10 have semiconductor elements 1.

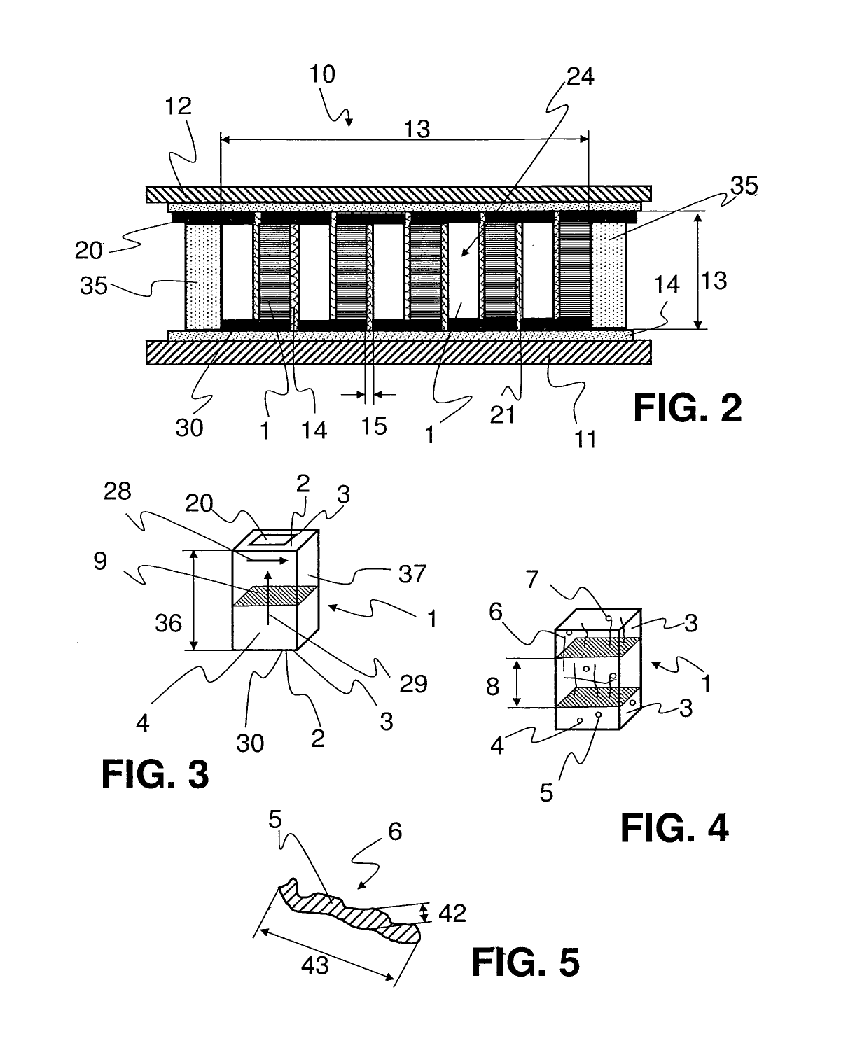

FIG. 2 shows an embodiment of a thermoelectric module 10, which in this case is of plate-shaped construction. The thermoelectric module 10 has a cold side 12 and, disposed opposite the latter, a hot side 11. An intermediate space 13, which is formed between the hot side 11 and the cold side 12, is formed delimited at the ends of the thermoelectric module 10 by closure elements 35. Semiconductor elements 1 are disposed within the intermediate space 13. The semiconductor elements 1 are connected to one another in alternating, electrically conductive fashion by first electrical conductor elements 20 and second electrical conductor elements 30. An insulation material or insulation 14 between the semiconductor elements 1 has a first thickness 15. The insulation material 14 correspondingly forms an electrical insulation 21 of the semiconductor elements 1. Furthermore, an insulation material 14 is formed between the first electrical conductor element 20 and the cold side 12 as well as between the second electrical conductor elements 30 and the hot side 11. The insulation material 14 on the hot side 11 and on the cold side 12 in this case is respectively assigned to the hot side 11 and to the cold side 12, and therefore not to the intermediate space 13. The intermediate space 13 is filled by material 24, specifically the insulation material 14 that forms the electrical insulation 21, by the first electrical conductor elements 20, by the second electrical conductor elements 30 and by the semiconductor elements 1. At least 99 vol % of the intermediate space 13 is filled by the material 24 in a solid state of aggregation. In particular, there are no gaseous or liquid inclusions present in the thermoelectric module 10.

FIG. 3 shows an embodiment of a cuboidal semiconductor element 1. The semiconductor element 1 extends between two mutually opposite ends 3 and is formed inter alia by a semiconductor material 4. The ends 3 form end face surfaces 2 on which first electrical conductor elements 20 and second electrical conductor elements 30 are disposed. The semiconductor element 1 has a height 36. The semiconductor element 1 is delimited laterally by side surfaces 37. The semiconductor element has cross sections 9 parallel to the ends 3. The cross sections 9 run in a first direction 28 parallel to the end face surfaces 2 of the ends 3. A second direction 29 extends transversely with respect to the first direction 28.

FIG. 4 shows a further embodiment of a cuboidal semiconductor element. The semiconductor element 1 has a central region 8 and ends 3. The semiconductor element 1 has not only the semiconductor material 4 but also a foreign material 5 which is present in the form of fibers 6 and grains 7.

FIG. 5 shows a foreign material 5 in the form of a fiber 6. In this case, the ratio of length 43 to second thickness 42 is two or more.

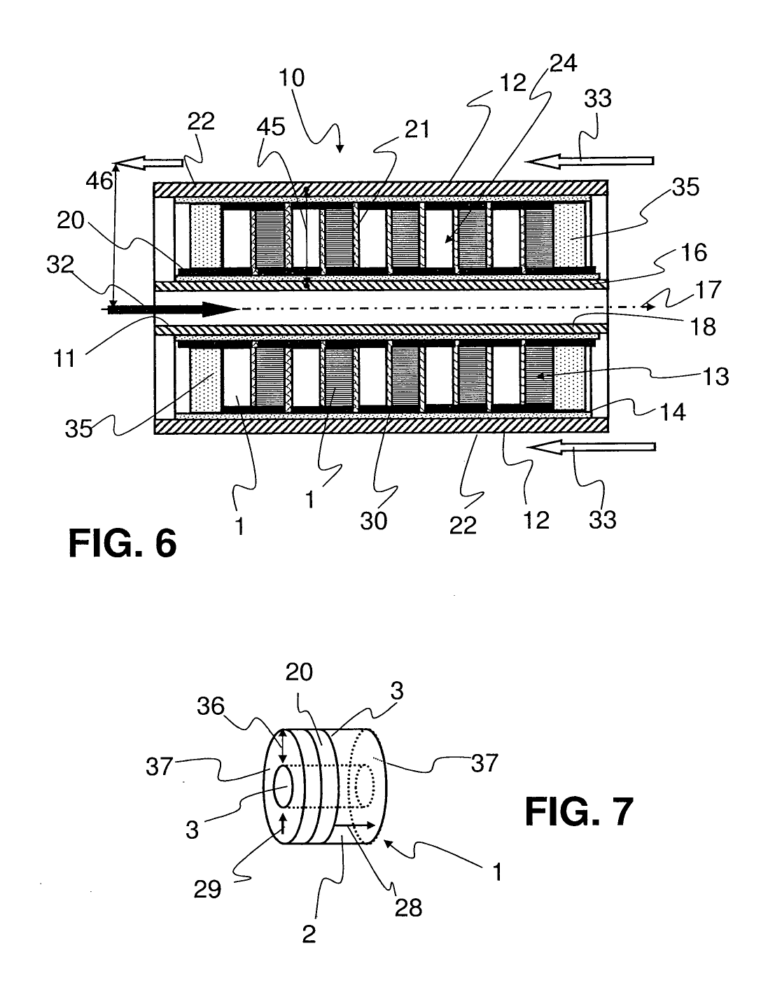

FIG. 6 shows a tubular embodiment of a thermoelectric module 10. In this case, a coolant 33 flows over the outside of the tubular thermoelectric module 10, in such a way that an outer tube 22 forms the cold side 12 of the thermoelectric module 10. An exhaust gas 32 flows through the interior of the thermoelectric module 10, in such a way that an inner tube 16 forms the hot side 11 of the thermoelectric module. In this case, the inner tube 16 and the outer tube 22 extend coaxially with respect to one another in the direction of an axis 17. The inner tube 16 has an inner circumferential surface 18 which is impinged on by the exhaust gas 32. The thermoelectric module 10 is delimited laterally by closure elements 35 which close off the intermediate space 13 between the outer tube 22 and the inner tube 16 toward the outside. Semiconductor elements 1 and electrical insulation 21 are disposed one behind the other in alternating fashion in the direction of the axis 17 in the intermediate space 13. The semiconductor elements 1 are connected to one another in electrically conductive fashion by first electrical conductor elements 20 in the region or vicinity of the inner tube 16. The semiconductor elements 1 are connected to one another in electrically conductive fashion by second electrical conductor elements 30 in the region or vicinity of the outer tube 22. The first electrical conductor elements 20 are separated from the inner tube 16, and the second electrical conductor elements 30 are separated from the outer tube 22, by electrical insulation material 14. The intermediate space 13 is filled by material 24, specifically insulation material 14 that forms electrical insulation 21, by the first electrical conductor elements 20, by the second electrical conductor elements 30 and by the semiconductor elements 1. At least 99 vol % of the intermediate space 13 is filled by the material 24 in a solid state of aggregation. In particular, there are no gaseous or liquid inclusions present in the thermoelectric module 10.

The electrical insulation 14 between the conductor elements and the respective inner tube 16 and outer tube 22 permits a good transfer of heat from the hot side 11 and the cold side 12 to the semiconductor elements 1. The electrical insulation 21 simultaneously has good thermal insulation characteristics, so that a transfer of heat from the hot side 11 to the cold side 12 through the electrical insulation 21 is substantially prevented. Furthermore, the heat transfer from the hot side 11 to the cold side 12 is limited by the foreign material 5 in the semiconductor elements 1 that is not shown in FIG. 6. In this way, the temperature difference 45 between the hot side 11 and the cold side 12 can be utilized in an efficient manner for the generation of electricity by the thermoelectric module 10. The temperature difference 45 is thus generally lower than the overall temperature difference 46 determined from the temperature of the exhaust gas 32 on the hot side 11 and the temperature of the coolant 33 on the cold side 12. In the region of the closure elements 35, the electrical current generated within the thermoelectric module 10 is conducted to the outside through the first electrical conductor elements 20 or the second electrical conductor elements 30.

FIG. 7 shows an embodiment of an annular semiconductor element. The annular semiconductor element 1 can be used in the tubular thermoelectric module 10 according to FIG. 6. The semiconductor element 1 shown therein has an annular form or shape such that the ends 3 are formed by an outer circumferential surface and an inner circumferential surface of the annular semiconductor element 1. The height 36 extends from one end 3 to the other end 3 of the semiconductor element 1. The semiconductor element 1 is delimited laterally by side surfaces 37. The ends 3 form the end face surfaces 2 of the semiconductor element 1. Non-illustrated cross sections 9 through the semiconductor element 1 run parallel to the end face surfaces 2 on the ends 3 of the semiconductor element 1. A first direction 28 likewise extends parallel to the end face surfaces 2, whereas a second direction 29 extends transversely with respect to the first direction 28. First electrical conductor elements 20 and non-illustrated second electrical conductor elements 30 (in this case on the inner circumferential surface) are disposed on the end face surfaces 2.

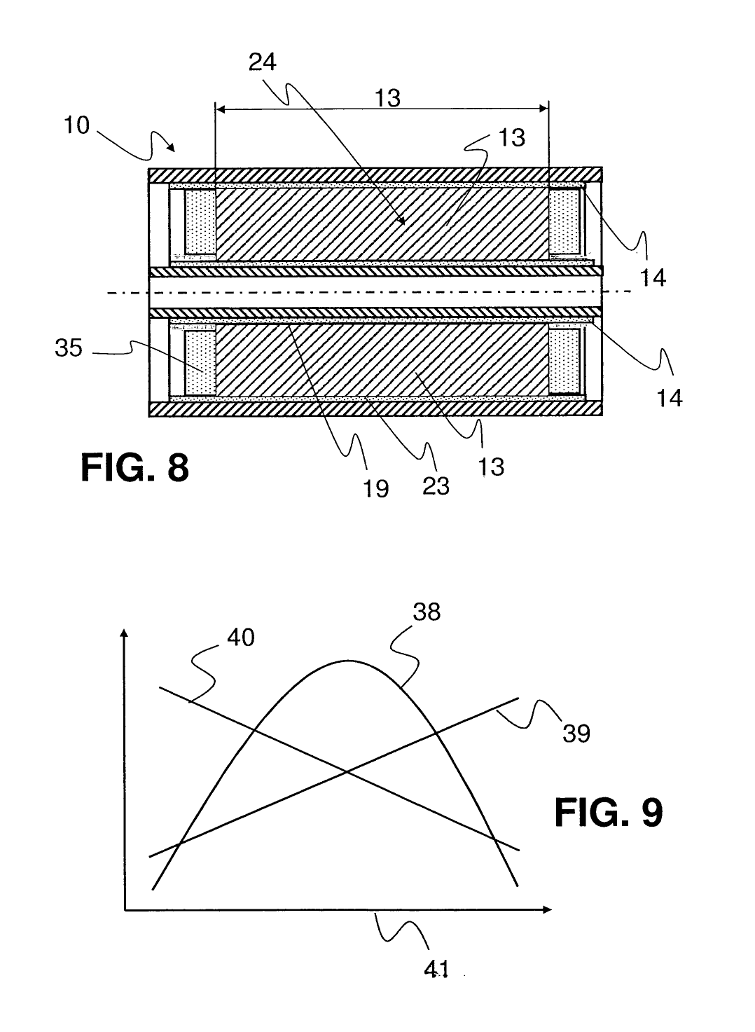

FIG. 8 shows a detail of the tubular structural variant of the thermoelectric module 10. The thermoelectric module 10 has the intermediate space 13 between the closure elements 35, a first outer circumferential surface 19 and a second outer circumferential surface 23. The electrically insulating insulation material 14 on the hot side 11 and on the cold side 12 is not assigned to the intermediate space 13. At least 99 vol % of the intermediate space 13 is filled by material 24 in a solid state of aggregation.

FIG. 9 shows a profile of an efficiency 39, of a heat flow 40 and of an electrical power 38 as a function of a thermal resistance 41 of the thermoelectric module 10. The thermal resistance 41 is plotted on the horizontal axis. With increasing thermal resistance 41 of the thermoelectric module 10, the temperature difference 45, that can be utilized for the generation of electricity, between the hot side 11 and cold side 12 of the thermoelectric module 10 increases. The thermoelectric efficiency 39 profits from an increasing temperature difference 45 in an approximately linear manner. In exchange for this, however, the heat flow 40 passing through the thermoelectric module 10 decreases because, with increasing thermal resistance 41 of the thermoelectric module 10, the overall resistance (sum of R_{convective} and R_{module}) also increases. There is thus a maximum power of the overall configuration which is dependent on the thermal resistance 41. It can be assumed, by way of approximation, that the electrical power 38 is at a maximum when half of the overall temperature difference 46 (exhaust gas 32 relative to coolant 33) prevails across the thermoelectric module 10, that is to say between the hot side 11 and the cold side 12 (temperature difference 45).

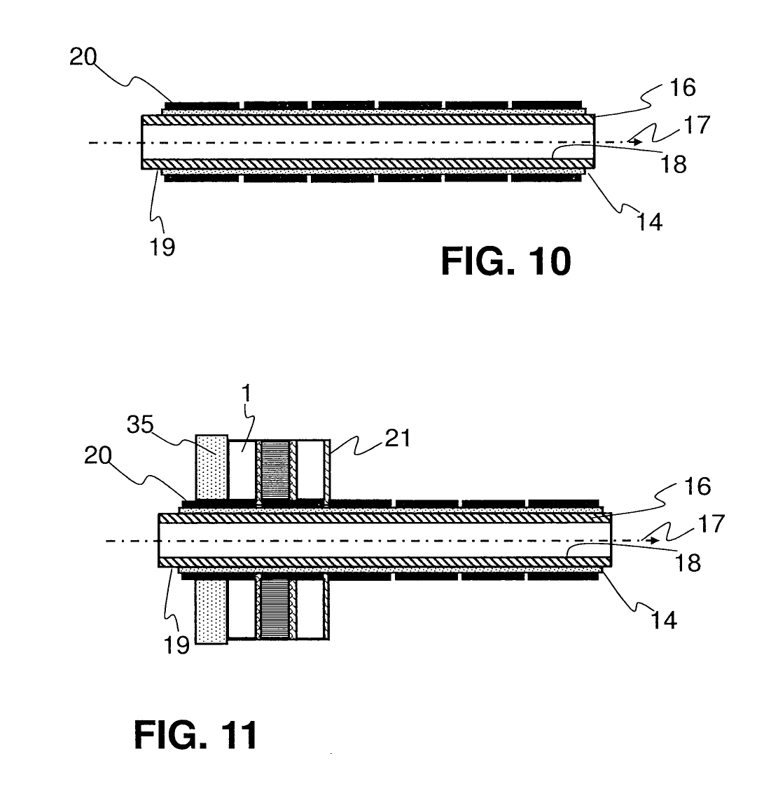

FIG. 10 shows method step a) of the method according to the invention. An inner tube 16 is provided which extends along an axis 17 and which has an inner circumferential surface 18 and a first outer circumferential surface 19. First electrical conductor elements 20, which are disposed on the first outer circumferential surface 19, are constructed to be electrically insulated with respect to the inner circumferential surface 18 by an insulation material 14.

FIG. 11 shows method step b) of the method according to the invention. Closure elements 35 are now disposed on the configuration according to FIG. 10 and, following these, semiconductor elements 1 (n-doped and p-doped) situated adjacent one another in alternating fashion. In each case one electrical insulation 21 is disposed between two semiconductor elements 1. In particular, the semiconductor elements 1 and the electrical insulation 21 are pushed onto the configuration according to FIG. 10, in the form of annular elements.

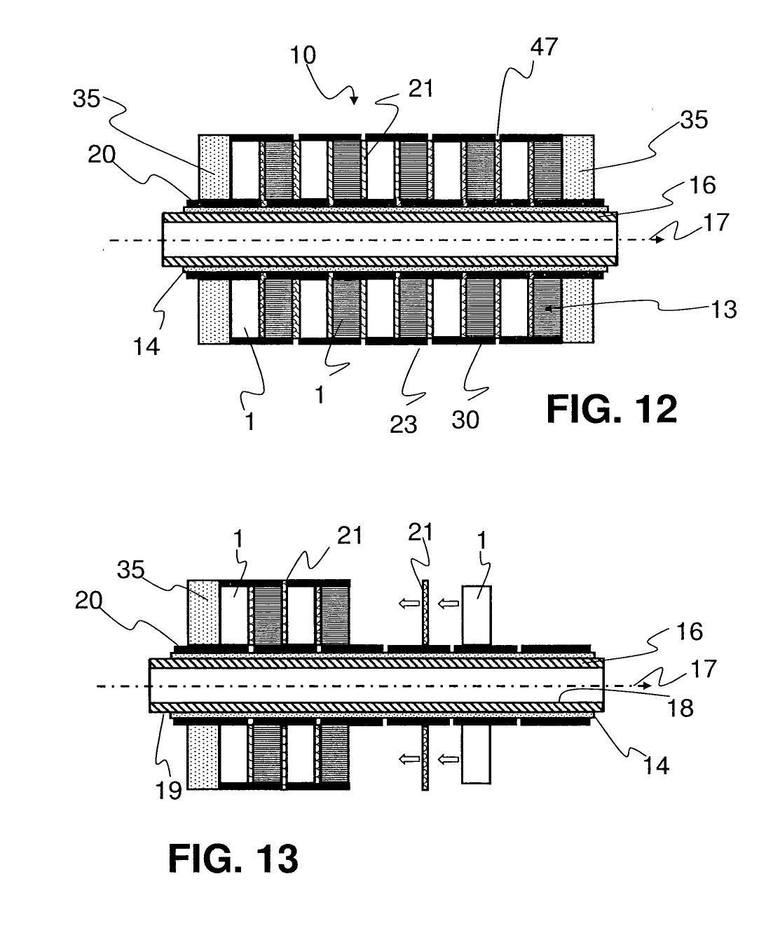

FIG. 12 shows method step c) of the method according to the invention. In this case, a thermoelectric module 10 has already been formed. Closure elements 35 and n-doped and p-doped semiconductor elements 1 are now disposed on the inner tube 16. The semiconductor elements 1 are connected in alternating, electrically conductive fashion at the inside by first electrical conductor elements 20. Correspondingly thereto, second electrical conductor elements 30 are disposed radially at the outside on the semiconductor elements 1. The second electrical conductor elements may be electrically insulated from one another by an external electrical insulation 47. The second electrical conductor elements 30 correspondingly form (together with the external electrical insulation 47) a second outer circumferential surface 23. The intermediate space 13 of the thermoelectric module 10 is correspondingly formed between the second outer circumferential surface 23 and the insulation material 14 disposed on the inner tube 16 and the closure elements 35.

FIG. 13 shows a further variant of method step b) of the method according to the invention. Semiconductor elements 1 and electrical insulation 21 are pushed alternately onto the configuration according to FIG. 10 in the direction of the axis 17. The second electric conductor elements 30 are electrically insulated from one another in the direction of the axis 17 by the electrical insulation 21. Thus, different electrical insulation 21 is used, in each case in a manner dependent on whether or not adjacent semiconductor elements 1 are connected to one another by second electrical conductor elements 30.

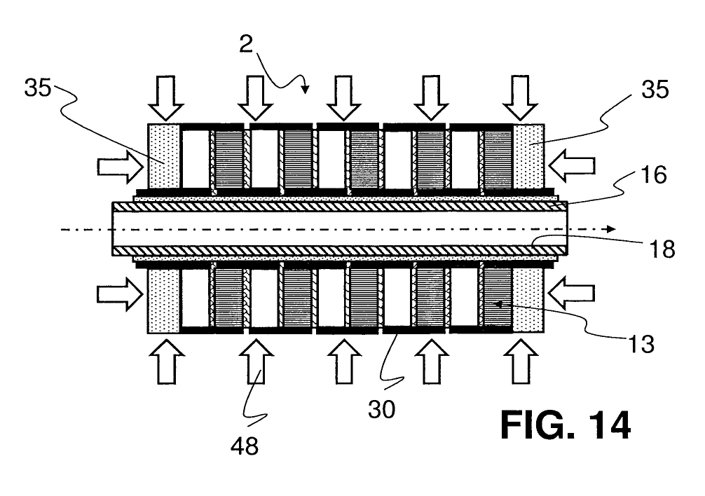

FIG. 14 shows method step d) of the method according to the invention. The thermoelectric module 10 is compacted by the exertion of a pressure 48, if appropriate with the application of a certain temperature.

1. A semiconductor element for a thermoelectric module, the semiconductor element comprising:
mutually opposite ends;
an n-doped or p-doped semiconductor material; and
at least one foreign material mixed with said semiconductor material, said at least one foreign material forming a fraction of 5 to 75 vol % of the semiconductor element.

2. The semiconductor element according to claim 1, wherein said at least one foreign material has, in a temperature range from 20 to 600° C., at least one characteristic selected from the following group:
at least one of greater tensile strength or yield strength than said semiconductor material,
lower specific thermal conductivity than said semiconductor material, and
lower electrical conductivity than said semiconductor material.

3. The semiconductor element according to claim 1, wherein said at least one foreign material is present in the form of at least one of fibers or grains.

4. The semiconductor element according to claim 3, wherein said grains are present in said at least one foreign material in a fraction of at least 30 vol %.

5. The semiconductor element according to claim 3, which further comprises:
a central region between said ends;
said grains and said fibers being distributed differently in the semiconductor element; and
at least one of:
said grains being present in a greater fraction than said fibers at said ends, or
said fibers being present in a greater fraction than said grains in said central region.

6. The semiconductor element according to claim 1, wherein:
said at least one foreign material is present at least in the form of fibers; and
said fibers are substantially disposed in at least one of:
a first direction parallel to said ends, or
a second direction transversely to said first direction.

7. The semiconductor element according to claim 1, wherein every cross section of the semiconductor element running parallel to said ends has a fraction of said at least one foreign material lying in a range between 25% and 75%.

8. A thermoelectric module, comprising:
a hot side, a cold side and an intermediate space disposed between said hot and cold sides; and
semiconductor elements disposed in said intermediate space;
said semiconductor elements each having mutually opposite ends, an n-doped or p-doped semiconductor material, and at least one foreign material mixed with said semiconductor material, said at least one foreign material forming a fraction of 5 to 75 vol % of said semiconductor element;
said semiconductor elements being electrically conductively connected to one another; and
at least 80 vol % of said intermediate space being filled with said semiconductor elements.

9. The thermoelectric module according to claim 8, which further comprises insulation material having a first thickness of less than 0.5 mm, said insulation material separating each two mutually adjacently disposed semiconductor elements from one another.

10. The thermoelectric module according to claim 9, wherein said insulation material is a mica material.

11. The thermoelectric module according to claim 8, which further comprises material in a solid state of aggregation forming at least 99 vol % of said intermediate space.

12. A method for producing a tubular thermoelectric module, the method comprising the following steps:
a) providing an inner tube having an axis, an inner circumferential surface, a first outer circumferential surface and first electrical conductor elements disposed on the first outer circumferential surface and electrically insulated from the inner circumferential surface;
b) placing n-doped and p-doped semiconductor elements in alternation along the axis and placing a respective electrical insulation between each two of the semiconductor elements;
c) placing second electrical conductor elements radially outwardly of the semiconductor elements to outwardly electrically conductively interconnect each two mutually adjacently disposed semiconductor elements and form a second outer circumferential surface after step c); and
d) compacting the thermoelectric module.

13. The method according to claim 12, which further comprises placing an outer tube on the second outer circumferential surface after step c), and only subsequently performing the compaction step d).

14. A motor vehicle, comprising:
a heat source;
a cooling configuration; and
a thermoelectric module disposed between said heat source and said cooling configuration, said thermoelectric module including:
a hot side, a cold side and an intermediate space disposed between said hot and cold sides; and
semiconductor elements disposed in said intermediate space, said semiconductor elements each having mutually opposite ends, an n-doped or p-doped semiconductor material, and at least one foreign material mixed with said semiconductor material, said at least one foreign material forming a fraction of 5 to 75 vol % of said semiconductor element, said semiconductor elements being electrically conductively connected to one another, and at least 80 vol % of said intermediate space being filled with said semiconductor elements.

15. A motor vehicle, comprising:
a heat source;
a cooling configuration; and
a thermoelectric module disposed between said heat source and said cooling configuration, said thermoelectric module including:
a) an inner tube having an axis, an inner circumferential surface, a first outer circumferential surface and first electrical conductor elements disposed on said first outer circumferential surface and electrically insulated from said inner circumferential surface;
b) n-doped and p-doped semiconductor elements alternately disposed along said axis, and electrical insulation disposed between each respective two of said semiconductor elements;
c) second electrical conductor elements disposed radially outwardly of said semiconductor elements and outwardly electrically conductively interconnecting each two mutually adjacently disposed semiconductor elements to form a second outer circumferential surface; and
d) said thermoelectric module being compacted.
